(19) United States
(12) Patent Application Publication
(10) Pub. No.: US 2009/0151768 A1
(43) Pub. Date: Jun. 18, 2009

(54) HEAT TRACING APPARATUS WITH HEAT-DRIVEN PUMPING SYSTEM

(76) Inventor: David John FORSETH, Cherry Point (CA)

Correspondence Address: DONALD V. TOMKINS;C/O TOMKINS LAW OFFICE, 740, 10150 - 100 STREET, EDMONTON, AB, T5J 0P6, CA

(21) Appl. No.: 12/337,348

(22) Filed: Dec. 17, 2008

Related U.S. Application Data
(60) Provisional application No. 61/014,628, filed on Dec. 18, 2007.
(60) Provisional application No. 61/086,865, filed on Aug. 7, 2008.

(51) Int. Cl. H01L 35/00

(52) U.S. Cl. 136/207

(57) ABSTRACT

In a heat tracing system using heat from a radiant heater to heat a circulating fluid, thermoelectric generation modules are used to generate electricity for powering a circulating pump. Thermoelectric power generation modules are sandwiched between a heat-absorbing plate and a heat sink, and this assembly is positioned with the heat-absorbing plate adjacent to a radiant heater. A conduit loop passes through the heat sink, such that a fluid circulating through the conduit is heated from heat drawn from the heater into the heat sink. Due to the temperature differential between the hot and cold sides of the thermoelectric modules, the modules produce electricity to power the pump circulating the fluid through the conduit loop. Supplementary heat exchanger components may be provided for additional fluid-heating capacity, and thereby increasing the amount of heat available for the heat tracing loop.

### CROSS-REFERENCE TO RELATED APPLICATIONS

This application claims the benefit, pursuant to 35 U.S.C. 119(e), of U.S. Provisional Application No. 61/014,628, filed on Dec. 18, 2007, and U.S. Provisional Application No. 61/086,865, filed on Aug. 7, 2008, and both said provisional applications are incorporated herein by reference in their entirety.

### FIELD OF THE INVENTION

The present invention relates in general to systems for heating and circulating a fluid, and in particular to such systems that use catalytic heaters both to heat the fluid and to power a pump for circulating the fluid through a conduit loop, such as for heat tracing.

### BACKGROUND OF THE INVENTION

It is well known to use heat from a catalytic heater (such as a Cata-Dyne™ heater, manufactured by CCI Thermal Technologies Inc. of Edmonton, Alberta, Canada) to heat a reservoir of fluid (such as glycol) for circulation through a heat tracing loop, for purposes such as thawing or preventing freezing of wellheads in cold climates. Examples of such applications can be found in U.S. Pat. No. 6,776,227 (Beida et al.), U.S. Pat. No. 7,138,093 (McKay et al.), and U.S. Pat. No. 7,293,606 (Benoit et al.). These systems require a pump to circulate the heated fluid through the heat tracing loop. However, since the heat tracing systems are commonly installed in remote locations (e.g., wellsites in northern Canada), the use of electrically-driven pumps is often not a practical option since the nearest electrical grid may be very far away. Solar power is not an ideal solution to this problem, because the pumps need to be operated extensively if not continuously during very cold conditions, and the available sunlight may be minimal during such periods (especially in the far north). Accordingly, the use of electric pumps powered by solar panels typical entails the provision of substantial battery back-up for when the sun is not shining.

For the foregoing reasons, there is a need for more practical methods and systems for providing electrical power for electric pumps in conjunction with heat tracing systems using catalytic heaters. The present invention is directed to this need.

### BRIEF SUMMARY OF THE INVENTION

In general terms, the present invention is a system and apparatus for heating a circulating fluid, using heat from a heater (such as a catalytic heater fuelled by natural gas or propane) both to heat the fluid and to generate electricity to power a pump for circulating the fluid through a conduit system (such as a heat tracing loop). In particular embodiments, the system produces sufficient electricity to serve needs over and above the power requirements of the circulating pump.

In accordance with the present invention, electric power is generated thermoelectrically, using heat from a suitable heater, and preferably a catalytic heater. The principles of thermoelectric power generation have been understood and applied for many years. If is known (in accordance with a scientific principle called the “Seebeck effect”) that electrical power can be produced in a thermocouple comprising “p-type” (i.e., positive) and “n-type” (i.e., negative) thermoelectric elements or modules which are connected electrically in series and thermally in parallel, by pumping heat from one side (the “hot side” or “hot junction”) of the thermocouple to the other side (the “cold side” or “cold junction”). This will generate an electrical current proportional to the temperature gradient across the thermocouple (i.e., between the hot and cold sides).

In the present invention, one or more thermoelectric generation modules (commonly referred to as “TEG modules”) are interposed or “sandwiched” between a heat-absorbing plate and a heat sink. For purposes of this patent document, any assembly of a heat-absorbing plate, one or more TEG modules, and a heat sink will be referred to as a “TEG board”. The TEG board is positioned with its heat-absorbing plate adjacent to (and preferably generally parallel to) a radiant heater, with an air space between the-heat-absorb plate and the heater. The sides of the TEG modules adjacent to the heat-absorbing plate will thus be the hot sides, and the other sides of the TEG modules (i.e., adjacent to the heat sink) will be the cold sides. A conduit loop passes through the heat sink, such that a fluid circulating through the conduit will be heated from heat drawn from the heater into the heat sink. The fluid is circulated by an electric pump. Due to the temperature differential between the hot and cold sides of the TEG modules (enhanced by the heat transfer from the heat sink into the circulating fluid), electrical power is produced by the TEG modules, for powering the pump, and for other applications depending on the total power output of the system.

Accordingly, in one embodiment the present invention is an apparatus for generating electrical power, said apparatus comprising a catalytic heater and a plurality of thermoelectric modules each having a hot side and a cold side, wherein the hot sides of the thermoelectric modules are exposed to heat from the catalytic heater, and the cold sides of the thermoelectric modules are in thermally-conductive proximity to a heat sink, such that the thermoelectric modules produce an electric current for powering a pump for circulating heated fluid within a heat tracing conduit loop, and wherein the heat tracing conduit loop passes through the heat sink to dissipate heat therefrom.

In another embodiment, the invention is an apparatus for generating electrical power, in which the apparatus comprises a first heat-absorbing plate; a heat sink having a first side and a second side; and a first plurality of thermoelectric modules each having a hot side and a cold side, said modules being electrically interconnected, and sandwiched between the heat-absorbing plate and the first side of the heat sink, with their hot sides adjacent the heat-absorbing plate. When the apparatus is positioned closely adjacent to a radiant heat source, with the first heat-absorbing plate nearest the heat source, heat from the radiant heat source will pass through the first heat-absorbing plate and the thermoelectric modules and into the heat sink, thus activating the thermoelectric modules to produce electricity. Preferably, the heat sink comprises one or more blocks of heat-conducting material such as copper or aluminum, with each block having one or more channels to receive one or more fluid-carrying conduits.

In preferred embodiments, the apparatus includes:
(a) a collector tank having an inlet and an outlet, said collector tank being in fluid communication with the conduit loop, with the conduit loop's outlet section connected to the tank outlet of the tank, and with the conduit loop's return section connected to the tank inlet; and
(b) a pump for circulating a fluid through the conduit loop, said pump being energized by electrical power produced by the first plurality of thermoelectric modules in response to the flow therethrough of heat from the first radiant heater.

The apparatus optionally may include a supplemental heat exchanger incorporated into the conduit loop such that fluid flowing through the conduit loop will flow through the supplemental heat exchanger, with the supplemental heat exchanger being positioned so as to be exposed to heat from the first radiant heater.

### BRIEF DESCRIPTION OF THE DRAWINGS

Embodiments of the invention will now be described with reference to the accompanying figures, in which numerical references denote like parts, and in which:

FIG. 1 is cross-section through a TEG board assembly mounted in association with a catalytic heater in accordance with a first embodiment of the present invention.

FIG. 2 is an exploded elevation of the TEG board shown in FIG. 1.

FIG. 3 is a schematic elevation of a heat tracing system in accordance with a first embodiment of the present invention, incorporating a TEG board assembly as shown in FIGS. 1 and 2.

FIG. 4 is a schematic elevation of a heat tracing system in accordance with a second embodiment of the invention.

FIG. 5 is a cross-section through a heat tracing system in accordance with a third embodiment of the present invention.

FIG. 6 is an exploded elevation of a TEG board arrangement as in FIGS. 4 and 5, illustrating an exemplary TEG module layout.

FIG. 7 is a schematic layout of a heat tracing system incorporating “master” and “slave” embodiments of the present invention.

FIG. 8 schematically illustrates electrical circuitry for simultaneously charging a storage battery and energizing a fluid circulation pump using power generated by apparatus in accordance with an embodiment of the present invention.

### DETAILED DESCRIPTION OF THE PREFERRED EMBODIMENTS

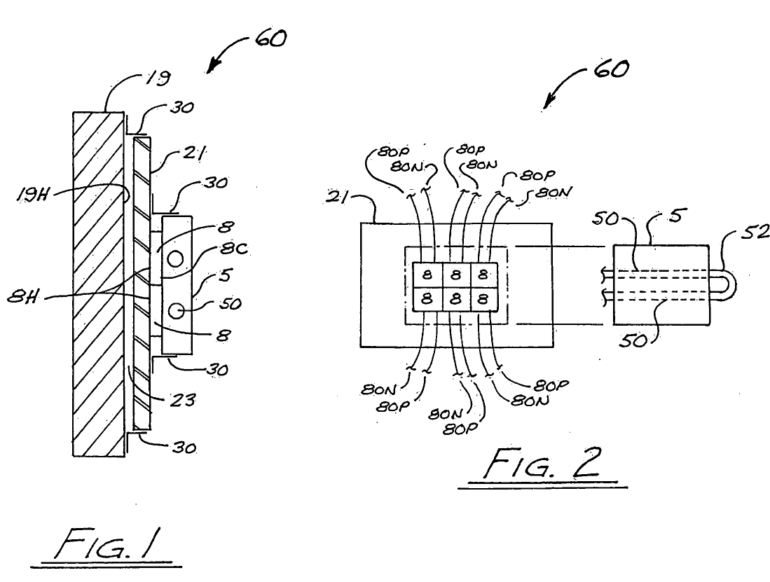

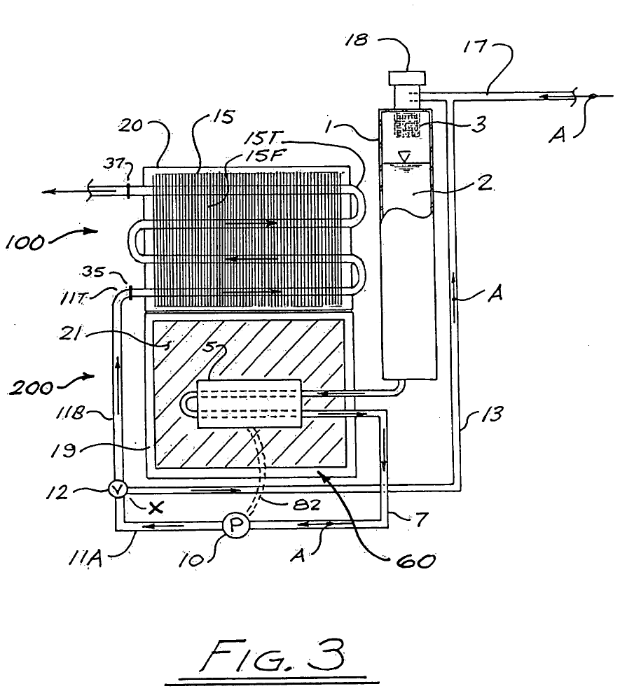

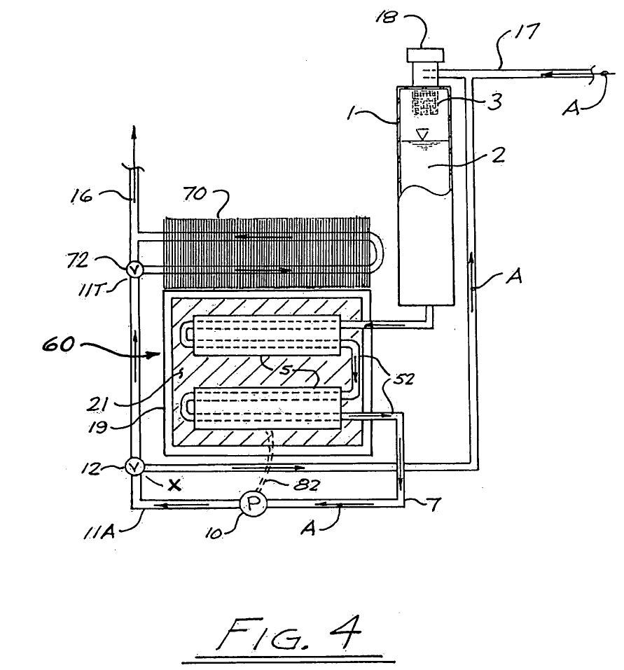

FIGS. 1, 2, and 3 illustrate one embodiment of the “TEG board” assembly 60 of a thermoelectric generation apparatus in accordance with the present invention. As schematically illustrated in FIG. 1, a cluster of TEG modules 8 are sandwiched between a heat-absorbing plate 21 (adjacent the hot sides 8H of modules 8) and a heat sink 5 (adjacent the cold sides 8C of modules 8). Each TEG module 8 has a positive lead wire 80P and a negative lead wire 80N. Although no corresponding electrical connection details are shown in the Figures, the lead wires 80P and 80N from the clustered TEG modules 8 are electrically connected as appropriate, in accordance with known principles and techniques, such that all electrical power developed by the TEG module cluster is available through power outlet cables 82 leading out from TEG board 60 as schematically illustrated in FIG. 3. FIG. 2 illustrates one possible configuration of the cluster of modules 8 (and here it is to be noted that the present invention is not dependent on the use of any particular number or arrangement of TEG modules 8).

TEG board assembly 60 is positioned with heat-absorbing plate 21 in close proximity to the heat-radiating face 19H of a first catalytic heater 19, thus initiating the thermoelectric process to generate an electrical current which can be used to power an electric pump to circulate heated fluid through a heat tracing loop. Preferably, an air space 23 will be provided between heat-absorbing plate 21 and first catalytic heater 19. Heat-absorbing plate 21 should be as close as possible to heater 19 to maximize heat transfer to plate 21, but not so close as to interfere with the availability of oxygen for proper catalytic reaction in heater 19. The width of air space 23 is variable to suit the size of heat-absorbing plate 21 and other design particulars for specific applications.

Brackets or other suitable connectors (as schematically represented by reference numeral 30) may be used to mount heat sink 5 to plate 21, and to mount plate 21 to heater 19. Connectors 30 preferably Will be designed and located to minimize any obstruction of vertical air flow through air space 23. In preferred embodiments, a heat exchanger face plate (not shown) is provided to cover heat exchanger 15 in order to minimize heat loss from heat exchanger 15 and thus maximize heat transfer to the fluid flowing through tubing 15T. For similar purposes, a suitable cover plate or enclosure (preferably insulated), may optionally be provided to enclose TEG board assembly 60.

In accordance with previously-stated principles, the current intensity will vary according to the total amount of heat passing from the hot side to the cold side of the TEG module cluster. Therefore, in order to maximize the current generated by a given number of TEG modules, it is desirable to maximize the temperature of the heat source to which the hot sides of the modules are exposed, and to minimize the temperature on the cold side—in other words, to maximize the temperature gradient.

The temperature at the face of a given catalytic heater will be essentially fixed, so increasing the temperature of the heat source will typically not be an option. However, the heat sink 5 has the effect of minimizing the cold-side temperature by absorbing or dissipating heat from the cold sides of the modules 8. The effectiveness of a heat sink varies according to the properties of the material used (specifically, its heat-conducting capacity) and the mass of the heat sink. In the preferred embodiment of the present invention, heat sink 5 is provided, preferably in the form of a thick block of a material that has a high coefficient of heat conductivity (for example, aluminum, copper, or other heat-conductive metal, or a heat-conductive non-metallic or sub-metallic composite material). In embodiments using an aluminum heat sink 5, the aluminum is preferably anodized (for greater service life) and painted black or some other dark colour (for enhanced heat absorption). In accordance with a particularly preferred embodiment, the effectiveness of heat sink 5 is enhanced by providing liquid cooling, in the form of fluid conduits 52 passing through channels 50 in heat sink 5. Heat will thus be transferred from heat sink 5 to, and carried away by, the fluid flowing in conduits 52, thus lowering the temperature of heat sink 5. In alternative embodiments, suitable fittings may be fitted to the ends of channels 50, to facilitate connection to conduits 52, such that conduits 52 do not actually pass through channels 50.

FIG. 3 illustrates an example of how the catalytic heat-driven thermoelectric power generation system of the present invention can be integrated with a conventional heat tracing system that uses a catalytic heater to heat the circulating heat tracing fluid. The upper section of the illustrated apparatus is a heat tracing section 100 comprising a fluid collector tank 1 which contains a fluid 2 (such as glycol). Collector tank 1 has a filler cap 18, and preferably also has a fine screen 3 to prevent particulate contaminants from entering collector tank 1. A heat exchanger 15 of suitable design is also provided, and in the illustrated embodiment is a finned-tube heat exchanger of well-known type, comprising tubing 15T (such as copper tubing) sinuously routed through an assembly of fins 15F (preferably painted black to maximize heat absorption). Tubing 15T has an inlet end 35 and an outlet end 37. A second catalytic heater 20 is positioned directly adjacent to heat exchanger 15 so that heat from second catalytic heater 20 will be transferred to fins 15F of heat exchanger 15 and thence to a fluid circulating through tubing 15T of heat exchanger 15. A loop of heat tracing conduit is also provided, with an outlet section 16 connected to the outlet end of tubing 15T, and a return section 17 connected to an upper region of collector tank 1 (preferably in association with filler cap 18 at a point above screen 3, as shown in FIG. 3). A heat exchanger face plate (not shown) is preferably provided to cover heat exchanger 15 in order to minimize heat loss from heat exchanger 15 and thus maximize heat transfer to the fluid flowing through tubing 15T.

In a conventional heat tracing apparatus of this sort, a further length of conduit or piping would extend from a lower region of collector tank 1 to a circulation pump and from the pump to the inlet end of the copper tubing of heat exchanger 15, thus completing the closed fluid conduit loop. In accordance with the present invention, however, heat tracing section 100 is coupled with thermoelectric generation apparatus 200 by running a fluid conduit from a lower region of collector tank 1 through heat sink 5 (through conduit section 52 in FIG. 3), then looping back through heat sink 5 (through conduit section 7) to an electric pump 10 (such as a vane pump), and thence, through conduit section 11, to inlet end 35 of tubing 15T of heat exchanger 15. The TEG module cluster of thermoelectric generation apparatus 200 is electrically connected to pump 10 by way of power outlet cables 82, such that actuation of first catalytic heater 19 will cause the generation of an electric current to power pump 10. Actuation of second catalytic heater 20 will cause heat tracing fluid 2 flowing through tubing 15T to be heated, whereupon it may be conveyed (by pump 10) through heat tracing outlet line 16 to a wellhead or other item needing heat. Heat tracing fluid 2 flows through return line 17 to collector tank 1 and thence through heat sink 5. Having lost heat to the wellhead or other heated item, the fluid 2 passing through heat sink 5 has significant capacity to absorb heat from heat sink 5; in this way, circulation of fluid 2 through heat sink 5 effectively preheats fluid 2 before it reaches heat exchanger 15.

The apparatus of the present invention preferably incorporates a by-pass conduit 13 to facilitate start-up of the system. As shown in FIG. 3, by-pass conduit 13 extends between return line 17 (preferably at a point close to collector tank 1) and a point X along conduit section 11 between pump 10 and inlet end 35 of tubing 15T of heat exchanger 15 (thus subdividing conduit section 11 into subconduit 11A between pump 10 and point X, and subconduit 11B between point X and a terminal end 11T, as shown in FIG. 3). A by-pass valve 12 is provided at point X. Valve 12 is operable between a normal position (in which fluid is free to flow from subconduit 11A into subconduit 11B) and a by-pass position (in which the flow of fluid from subconduit 11A into subconduit 11B is blocked, and is instead diverted into by-pass conduit 13). This by-pass circuit makes it possible to circulate fluid through heat sink 5 without having to circulate the fluid through heat exchanger 15 and the full heat tracing conduit loop (i.e., outlet section 16 and return section 17), which would require considerably more power.

Operation of the system may now be explained with reference to FIG. 3 and the foregoing description. To facilitate understanding of the system, FIG. 3 includes numerous arrows A indicating the flow direction of fluid 2 circulating through the sections of tubing and conduit in the system.

To start the system, the fuel supply (e.g., natural gas) to first and second catalytic heaters 19 and 20 is turned on, and first catalytic heater 19 is connected to battery power to initiate the catalytic reaction. By-pass valve 12 is then moved to the by-pass position. Once the catalytic reaction in first catalytic heater 19 is underway, heater 19 begins to direct infrared heat to heat-absorbing plate 21, beginning the thermoelectric generation process in TEG modules 8. In one tested experimental system, when the thermoelectrically-generated power reached a voltage of about 0.7 volts, pump 10 began to turn slowly, and started moving fluid through the by-pass circuit and through heat sink 5. The voltage spiked instantly as fluid started passing through heat sink 5. First catalytic heater 19 may then be disconnected from battery power. Second catalytic heater 20 may then be actuated by connecting it to battery power (which may be disconnected after the catalytic reaction in second catalytic heater 20 is well established).

When the voltage reaches a high enough level (about 5 volts in tested systems), by-pass valve 12 may be moved to the normal position, thus allowing fluid to circulate through the complete system. The thermoelectric generation apparatus will continually increase the voltage being supplied to pump 10 until it reaches a stabilized level (in approximately 30 minutes in tested systems). The system may be shut down by simply turning off the gas supply. As the heat being generated by first catalytic heater 19 dissipates, the electrical power being supplied to pump 10 will decrease until pump 10 quits.

The advantages of the present system will be readily appreciated by persons skilled in the art of the invention. The primary benefit is that so long as there is fuel for the catalytic heaters, there will be continuous electrical power to actuate the circulation pump. This eliminates the need for an external electrical power supply, and eliminates one of the main drawbacks of using solar power (e.g., intermittent or sporadic power generation; need for substantial storage battery back-up). The required battery power for the system is only what is needed to initiate the catalytic reactions in the catalytic heater (or heaters).

FIG. 4 illustrates an alternative embodiment that uses a single catalytic heater 19 to heat the circulating fluid and generate electrical power. In the primary configuration of this embodiment, fluid 2 is heated as it passes through conduits 52 and a pair of heat sinks 5. As shown in FIG. 4, however, supplemental heat exchanger means 70 (such as a finned tube section, as illustrated in FIG. 4) may optionally be mounted above catalytic heater 19 for enhanced fluid heating, with supplemental heat exchanger 70 (of any suitable type) incorporated into the main fluid conduit loop. Preferably, supplemental heat exchanger 70 is enclosed within an exhaust vent hood (not shown in FIG. 4) to maximize the amount of residual heat to which supplemental heat exchanger 70 is exposed. In embodiments incorporating supplemental heat exchanger 70, a secondary valve 72 is preferably provided at terminal end 11T, with, secondary valve 72 being operable between a first position allowing fluid 2 to circulate through supplemental heat exchanger 70 and thence into conduit outlet section 16, and a second position allowing fluid 2 to by-pass supplemental heat exchanger 70 and flow directly into conduit outlet section 16.

The embodiment shown in FIG. 4 uses a pair of elongate heat sinks 5, to increase the system's fluid-heating capacity and to facilitate the use of a larger number of TEG modules, thus increasing the system's power-generating capacity. In this heat sink arrangement, conduit 52 loops through both heat sinks 5. Persons skilled in the art of the invention will readily appreciate that one or more additional heat sinks could be incorporated into this or other alternative embodiments of the system without departing from the scope and principles of the present invention.

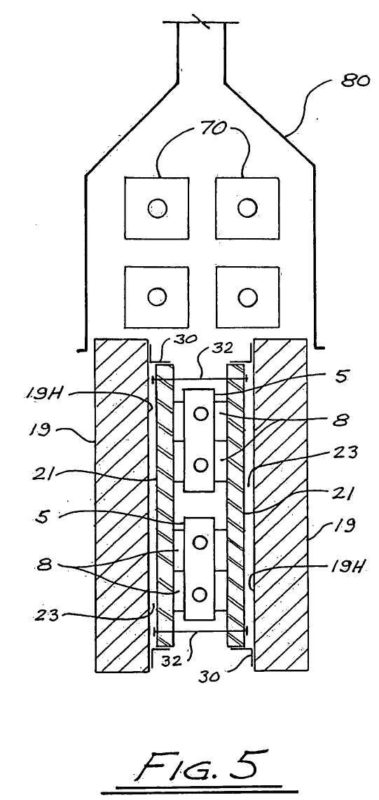

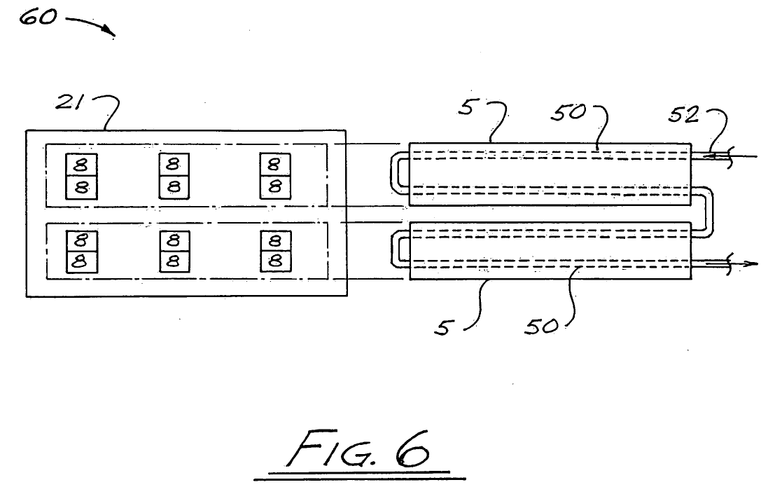

FIG. 5 illustrates a variant of the embodiment shown in FIG. 4 which uses a pair of catalytic heaters 19 mounted on either side of a modified or “double” TEG board assembly having two electrically-independent TEG module circuits. As shown in FIG. 5, the heat sink 5 or sinks (two heat sinks 5 being provided in the particular embodiment of FIG. 5) are sandwiched between a pair of heat-absorbing plates 21, with a cluster of TEG modules 8 provided on each side of each heat sink 5 so as to be sandwiched between the corresponding heat sink 5 and heat-absorbing plate 21. Brackets 30 and cross-ties 32 are shown in FIG. 5 to illustrate means for mounting heater 19 to the double TEG board assembly and for interconnecting the two heat-absorbing plates 21. Persons skilled in the art will appreciate, however, that these depictions are conceptual only, and that the present invention is in no way restricted to the use of any particular type of mounting or connection means.

As will be immediately apparent, this embodiment doubles the amount of heat available for heating the circulating fluid 2 and for electrical power generation, without increasing the number of heat sinks 5 required. Of course, it may be necessary or desirable to modify the size (and possibly the material properties) of heat sinks 5 in order to optimize the operational benefits of this arrangement, but it will generally be more efficient to use a given number of larger heat sinks 5 than a larger number of smaller heat sinks 5 having equivalent mass.

The user of two electrically-independent TEG module circuits facilitates use of the generated power for different purposes. For example, each TEG module circuit may have its own separate set of power outlet cables 82 (not shown in FIG. 5) such that the power output from one TEG module circuit may be dedicated to energizing fluid circulation pump 10, with power from the other circuit being used for battery charging or other purposes. Alternatively, all of the TEG modules may be connected such that the full electrical output of the system is carried by a single set of power outlet cables 82.

FIG. 5 illustrates supplemental heat exchanger elements 70 positioned above catalytic heaters 70, but such supplemental heat exchanger elements 70 are optional and not essential. In embodiments both with and without supplemental heat exchanger elements 70, an exhaust hood 80 is preferably provided above the heater/TEG board assembly as shown in FIG. 5. In embodiments having supplemental heat exchanger elements 70, said heat exchanger elements 70 are preferably enclosed within exhaust hood 80 in order to maximize the heat exposure of heat exchanger elements 70.

It will be readily appreciated that alternative embodiments of the present invention may use only a single heater 19 and only one TEG board assembly (rather than the double TEG board shown in FIG. 5), with or without supplemental heat exchanger elements 70, and with or without exhaust hood 80. One alternative embodiment uses an exhaust hood 80 that is configured to partially or completely house fluid collection tank 1, which will thus be exposed to waste heat from heater 19 (and heater 20 in certain embodiments).

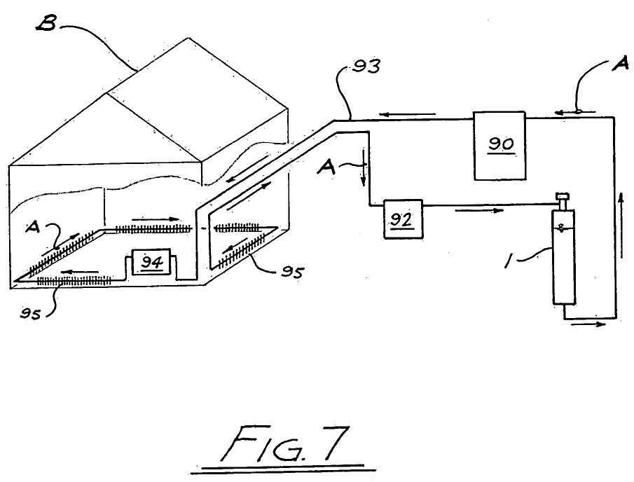

FIG. 6 illustrates a preferred TEG module arrangement for embodiments using a pair of elongate heat sinks 5 (such as shown in FIGS. 4 and 5). As previously noted, however, the present invention is not restricted to any particular number or arrangement of TEG modules 8, and persons skilled in the art will appreciate that many alternative TEG module arrangements are possible.

Although not specifically illustrated, a further embodiment using four catalytic heaters can be used in applications requiring greater fluid-heating and power-generating capabilities. This embodiment would essentially incorporate a system as in FIG. 5, with a “double” TEG board assembly disposed between a pair of lower catalytic heaters, plus a supplemental heater exchanger positioned above the double TEG board between a pair of upper catalytic heaters. In essence, this alternative embodiment would constitute a doubled-up version of the embodiment illustrated in FIG. 3.

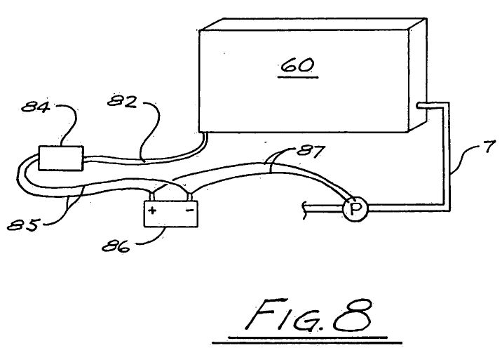

FIG. 7 schematically illustrates one example of how multiple embodiments of the present invention can be incorporated into a heat tracing circuit or a building heating system. In the illustrated layout, a “master” unit 90 in accordance with a selected embodiment of the apparatus of the invention, and complete with a pump (not shown in FIG. 7) and an associated fluid collector tank 1, is used for primary fluid-heating and power-generating purposes to circulate a heated fluid through a conduit system 93 to provide heat for a building B (or to circulate heated fluid through a heat tracing circuit to heat a well head or other installation). The illustrated building heating system also incorporates a “slave” unit 92, which again may be in accordance with any selected embodiment of the invention, but does not require a pump or an associated fluid collector tank. Slave unit 92 produces additional electrical power, and also serves as an effective heat exchanger to increase the temperature of the circulating fluid. Slave unit 92 may also (or alternatively) be used to provide primary or supplemental electrical power for charging one or more batteries (not shown), for use in start-up of master unit 90 or for other desired purposes. In preferred embodiments, slave unit 92 will be generally as shown in FIG. 4 or FIG. 5, but not necessarily including supplemental heat exchanger 70.

As shown in FIG. 7, fluid conduit system 93 provides heated fluid to suitable radiator elements 94 (such as hydronic finned baseboard heaters of known type) installed in building B. Direction arrows A indicate the direction of fluid flow through conduit system 93 and radiators 94. Additional heat may optionally be provided by one or more second stage heaters 95 incorporated into the conduit/radiator system. Second stage heater 95 may be of any suitable type, including a selected embodiment of the apparatus of the present invention (although power-generation capacity will not necessarily be required for second stage heater 95), or a heat exchanger/catalytic heater combination similar to upper section 100 of the apparatus shown in FIG. 3 (i.e., with no TEG board).

FIG. 8 schematically illustrates one possible system for using a TEG board assembly (in accordance with a selected embodiment of the apparatus of the present invention) to energize a fluid circulation pump while simultaneously charging a battery. FIG. 8 shows a TEG board assembly 60 with fluid conduit 7 running from TEG board 60 to pump 10, and with power outlet cables 82. For clarity and simplicity, the catalytic heater 19 and other components associated with TEG board 60 are not shown in FIG. 8. Using parallel circuitry as shown in FIG. 8, power outlet cables 82 are connected to a DC (i.e., direct current) converter or charge controller 84, while supplementary power cables 85 run from DC converter 84 to the terminals of a storage battery 86 (thus charging battery 86), and additional supplementary power cables 87 run from the terminals of battery 86 to energize fluid circulation pump 10.

The various embodiments of the apparatus of the present invention preferably will incorporate a thermal safety switch associated with heat sink 5 and electrically connected to a switch operable to shut off the flow of fuel gas (e.g., natural gas or propane) to heaters 19 and 20. The thermal safety switch will include a temperature probe for sensing the temperature of heat sink 5. Should the temperature of heat sink 5 rise above a predetermined temperature probe setting (due to failure of pump 10 or any other cause), the thermal safety switch will shut off the fuel gas supply. Persons skilled in the art of the invention will appreciate that various known technologies may be used or readily adapted to provide thermal safety shutdown means for use with the present invention.

It will also be readily appreciated by those skilled in the art that various modifications of the present invention may be devised without departing from the essential concept of the invention, and all such modifications are intended to come within the scope of the present invention and the claims appended hereto. It is to be especially understood that the invention is not intended to be limited to illustrated embodiments, and that the substitution of a variant of a claimed element or feature, without any substantial resultant change in the working of the invention, will not constitute a departure from the scope of the invention.

In this patent document, the word “comprising” is used in its non-limiting sense to mean that items following that word are included, but items not specifically mentioned are not excluded. A reference to an element by the indefinite article “a” does not exclude the possibility that more than one of the element is present, unless the context clearly requires that there be one and only one such element.

What is claimed is:

1. An apparatus for generating electrical power, said apparatus comprising a catalytic heater and a plurality of thermoelectric modules each having a hot side and a cold side, wherein the hot sides of the thermoelectric modules are exposed to heat from the catalytic heater, and the cold sides of the thermoelectric modules are in thermally-conductive proximity to a heat sink, such that the thermoelectric modules produce an electric current for powering a pump for circulating heated fluid within a heat tracing conduit loop, and wherein the heat tracing conduit loop passes through the heat sink to dissipate heat therefrom.

2. An apparatus for generating electrical power, said apparatus comprising:
(a) a first heat-absorbing plate;
(b) a heat sink having a first side and a second side; and
(c) a first plurality of thermoelectric modules each having a hot side and a cold side, said modules being electrically interconnected, and sandwiched between the heat-absorbing plate and the first side of the heat sink, with their hot sides adjacent the heat-absorbing plate;
such that when said apparatus is positioned closely adjacent to a radiant heat source, with the first heat-absorbing plate nearest the heat source, heat from the radiant heat source will pass through the first heat-absorbing plate and the thermoelectric modules and into the heat sink, thus activating the thermoelectric modules to produce electricity.

3. The apparatus of claim 2, wherein the heat sink comprises one or more blocks of a heat-conducting material, each said block having one or more channels therethrough, for receiving one or more fluid-carrying conduits.

4. The apparatus of claim 3, wherein the heat-conducting material of at least one of the one or more blocks comprises a metal selected from the group consisting of copper and aluminum.

5. The apparatus of claim 2, further comprising a second heat-absorbing plate and a second plurality of thermoelectric modules, said second plurality of thermoelectric modules being sandwiched between the second heat-absorbing plate and the second face of the heat sink.

6. An apparatus for generating electrical power, said apparatus comprising:
(a) a first heat-absorbing plate;
(b) a heat sink having a first side and a second side;
(c) a first plurality of thermoelectric modules each having a hot side and a cold side, said first plurality of thermoelectric modules being electrically interconnected, and sandwiched between the first heat-absorbing plate and the first side of the heat sink, with their hot sides adjacent the first heat-absorbing plate; and
(d) a first radiant heater having a heat-radiating face;
wherein the subassembly comprising the first heat heat-absorbing plate, the first plurality of thermoelectric modules, and the heat sink is mounted closely adjacent to the first radiant heater, with the first heat-absorbing plate nearest the heat-radiating face of the first radiant heater.

7. The apparatus of claim 6, further comprising a closed conduit loop passing through the heat sink, and said conduit loop having an outlet section and a return section.

8. The apparatus of claim 7, further comprising;
(a) a collector tank having an inlet and an outlet, said collector tank being in fluid communication with the conduit loop, with the conduit loop's outlet section connected to the tank outlet of the tank, and with the conduit loop's return section connected to the tank inlet; and
(b) a pump for circulating a fluid through the conduit loop, said pump being energized by electrical power produced by the first plurality of thermoelectric modules in response to the flow therethrough of heat from the first radiant heater.

9. The apparatus of claim 8 wherein the first radiant heater is a catalytic heater fuelled by natural gas.

10. The apparatus of claim 8, further comprising supplemental heat exchanger means incorporated into the conduit loop, said supplemental heat exchanger means being connected into the conduit loop such that fluid flowing through the conduit loop will flow through the supplemental heat exchanger means, and said supplemental heat exchanger means being positioned so as to be exposed to heat from the first radiant heater.

11. The apparatus of claim 10 wherein the supplemental heat exchanger means comprises finned tubing.

12. The apparatus of claim 8, further comprising:
(a) supplemental heat exchanger incorporated into the conduit loop, such that fluid flowing through the conduit loop downstream of the heat sink can flow through the supplemental heat exchanger; and
(b) a second radiant heater having a heat-radiating face, said second radiant heater being positioned with its heat-radiating face adjacent to the supplemental heat exchanger.

13. The apparatus of claim 12 wherein the supplemental heat exchanger means comprises finned tubing.

14. The apparatus of claim 8, further comprising;
(a) a second heat-absorbing plate
(b) a second plurality of thermoelectric modules each having a hot side and a cold side, said second plurality of thermoelectric modules being electrically interconnected, and sandwiched between the second heat-absorbing plate and the second side of the heat sink, with their hot sides adjacent the second heat-absorbing plate; and
(c) a second radiant heater having a heat-radiating face;
wherein the second heat-absorbing plate is positioned adjacent the heat-radiating face of the second radiant heater.

15. The apparatus of claim 8, wherein the heat sink comprises one or more blocks of heat-conducting metal, each said block having one or more channels therethrough, for receiving one or more fluid-carrying conduits.

16. The apparatus of claim 8, wherein the heat-conducting metal of at least one of the one or more blocks comprises aluminum.

17. The apparatus of claim 12, further comprising a by-pass conduit and an associated by-pass valve, said by-pass valve being operable between a first position in which fluid is free to flow through the heat sink and thence through the supplemental heat exchanger, and a second position in which fluid will flow through the heat sink but not through the supplemental heat exchanger.
